(19) United States
(12) Patent Application Publication
(10) Pub. No.: US 2025/0120035 A1
(43) Pub. Date: Apr. 10, 2025

(54) Modular rack with adjustable size structures

(71) Applicants: Mark David Ortenzi, Escondido, CA (US); Chris Orlando, Escondido, CA (US)

(72) Inventors: Mark David Ortenzi, Escondido, CA (US); Chris Orlando, Escondido, CA (US)

(21) Appl. No.: 18/488,748

(22) Filed: Oct. 17, 2023

Related U.S. Application Data
(60) Provisional application No. 63/588,252, filed on Oct. 5, 2023.

(51) Int. Cl. H05K 7/14; H05K 7/20

(52) U.S. Cl. CPC H05K 7/1488; H05K 7/20754

(57) ABSTRACT

An equipment rack, is formed to be adjustable in width. The left side of the rack is movable relative to a right side of the rack, to increase the distance between the left side of the rack in the right side of the rack. A guide plate is tightened to hold the rack in position, thereby allowing the rack to be adjusted between different widths and held in position at those different widths. A blanking plate can be located on the top of the rack to maintain the opening in the top of the rack being the same size even when the rack is adjusted in width.

This application claims priority from provisional application No. 63/588,252, filed Oct. 5, 2023, the entire contents of which are herewith incorporated by reference.

### BACKGROUND

Computing equipment such as servers are often housed within a sealed or sealable housing rack. The rack can include structure to hold the different servers. Different servers have different sizes.

### SUMMARY

The present application describes a modular rack that can be reconfigured between different sizes and has different structure allowing parts to be moved in and out of, and held into the rack. With the new ability to change the with diameter of the rack it will allow for custom size pre racked computer gear without modification and allowing footprint to change as needed.

An embodiment describes a modular rack with adjustable size structures of a type allowing the newer “Open Compute Platform” or OCP designs along with the ability to take current pre-developed rack deployments without having to re-rack and re-cable

### BRIEF DESCRIPTION OF THE DRAWINGS

Aspects of the drawings are described within with reference to the accompanying drawings

FIG. 1 illustrates a perspective view of the rack

FIG. 2 shows a side view of the rack from a different angle, illustrating the horizontal rails

FIG. 3 shows a bottom detail of the rack 300

FIG. 4 illustrates the front of the rack

FIG. 5 illustrates how the front of the ramp can be ramped

FIG. 6 shows the front view;

FIG. 7 shows a top section of the rack;

FIG. 8 shows the rack is closed at the top, and fitted with cooling equipment; and

FIG. 9 shows adjustable racks.

### DETAILED DESCRIPTION

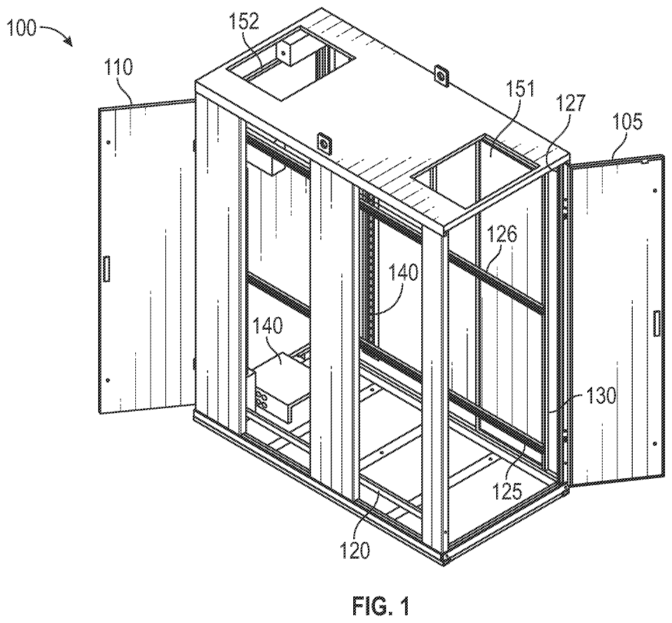

FIG. 1 illustrates a perspective view of the rack according to an embodiment. The rack 100 opens at its front with a front door 105 and at the rear via a rear door 110. Rack holding rails 120, 125 run inside the rack to hold the servers therein which will be held within the rack. The rack holding rails hold structure for holding the rack, along with vertical rails 130, hold structure for holding the servers inside the rack. The front vertical rail 130 (and a corresponding rail on the other side) is typically spaced 18 inches from the front of the rack in order to allow air flow through the front of the rack.

There are also open areas at the top of the rack 151, 152 through which power and cooling are provided as shown herein. In one embodiment, a cooling system can be located on the top of the rack.

As explained herein, there are also openings at the bottom of the rack to maintain airflow under the rack, and openings at the rear of the rack. To maintain airflow behind the rack.

The rear rail 140 according to the present application can be reconfigured depending on the depth of the servers that are placed into the racks.

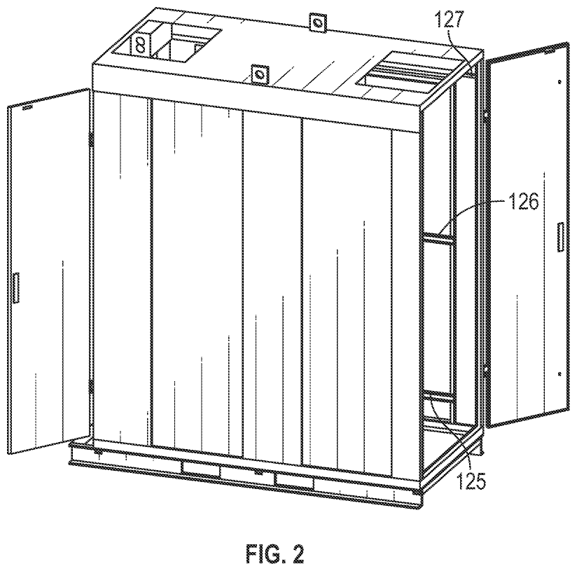

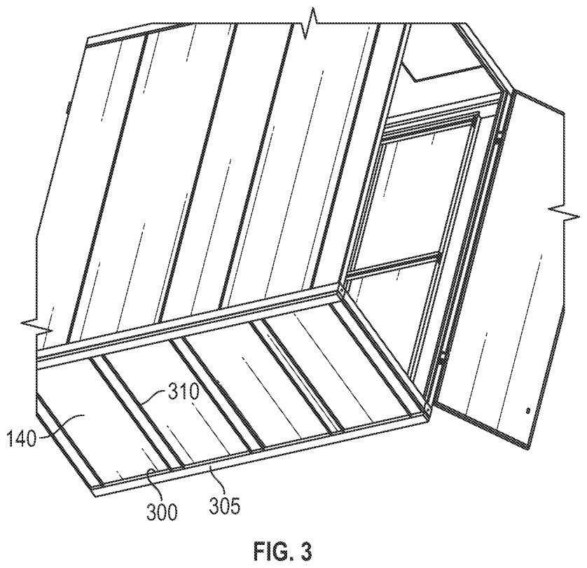

FIG. 2 shows a side view of the rack from a different angle, illustrating the horizontal rails 125,126, 127. While this shows only three horizontal rails, it should be understood that there can be many more rails to fit more shelves into the single rack.

FIG. 3 shows a bottom detail of the rack 300 illustrating the structural supports 305 and crossbars 310. The location of the rear rail 140 is also shown.

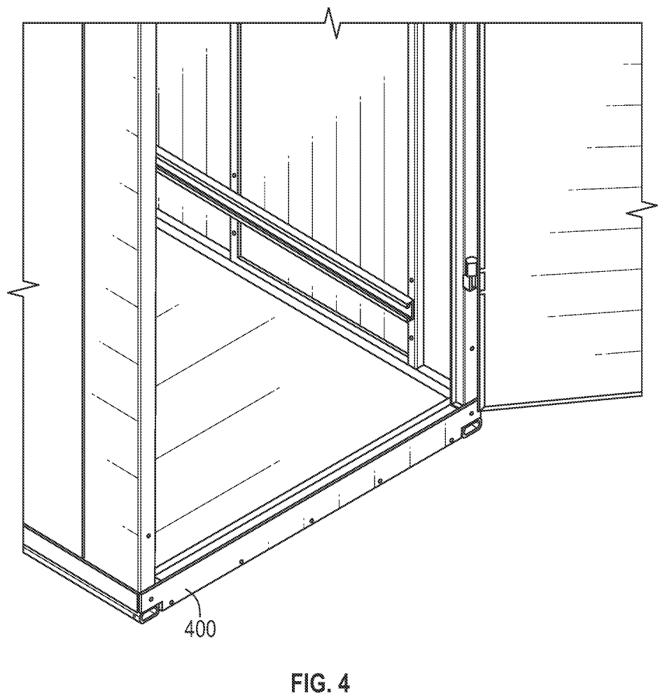

FIG. 4 illustrates the front of the rack, with a structural crossbar 400 spacing the bottom area of the rack from the floor. The structural crossbar causes this bottom area to be 3 to 4 inches off the ground to enable airflow under the rack.

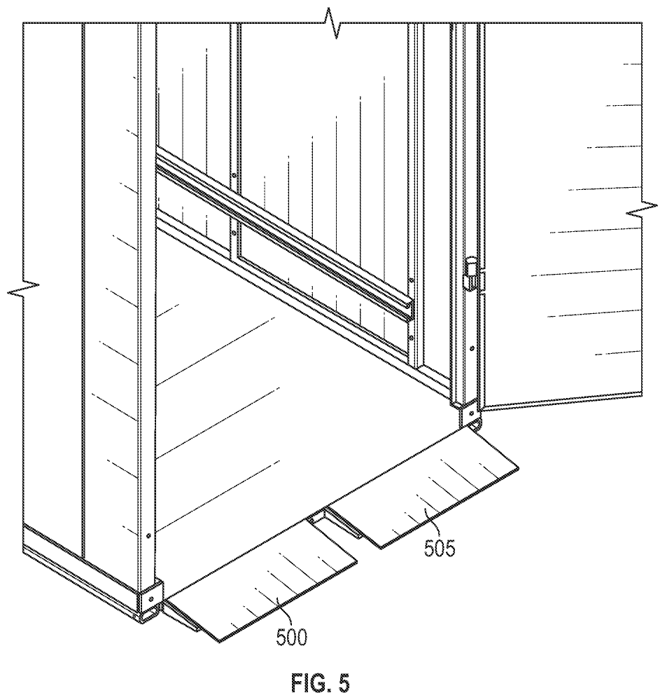

FIG. 5 illustrates how the front of the ramp can be ramped with ramps 500, 505 which ramp up enabling heavy loads to be wheeled into the cabinet.

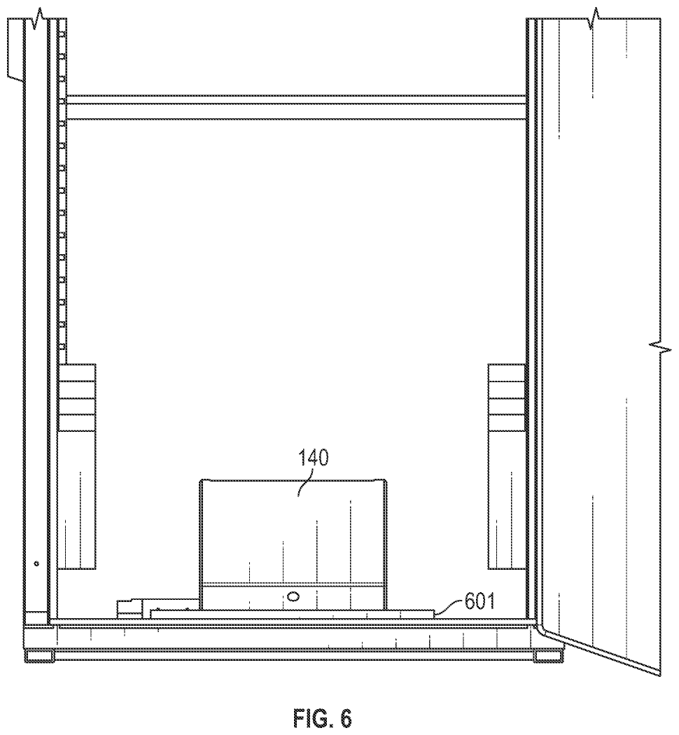

FIG. 6 shows a front view, illustrating the rear rail 140 at the rear of the cabinet. The rear rail has a bottom piece 601 whose top is located at the same level as the top surface of the bottom of the rack, e.g., 3 to 4 inches off the ground. The back facing piece of the rear rail extends upward from the bottom piece, and forms a back surface facing to the back of the servers that are in the rack. This surface can form a backstop to the racks, or can form a surface to provide, for example, power to the rack. Moreover, since this enforces the spacing under the rack, it facilitates cooling by providing an area under the rack for airflow, and the rear of this same rear rail maintains the airflow behind the servers mounted in the rack.

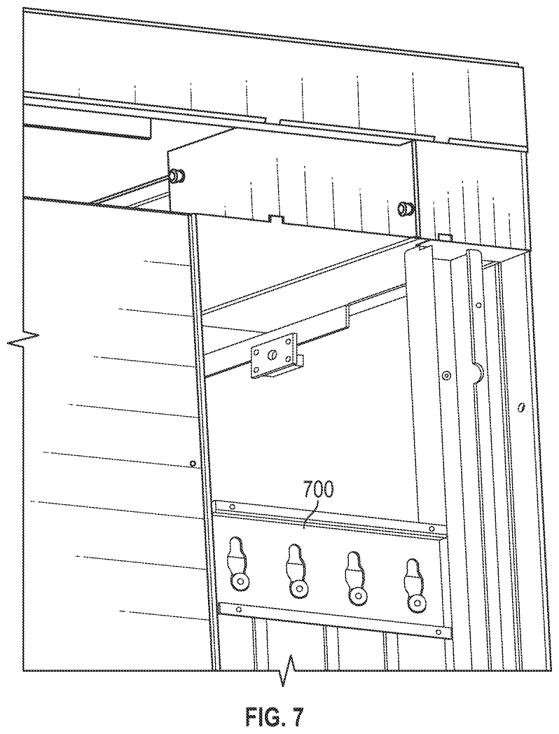

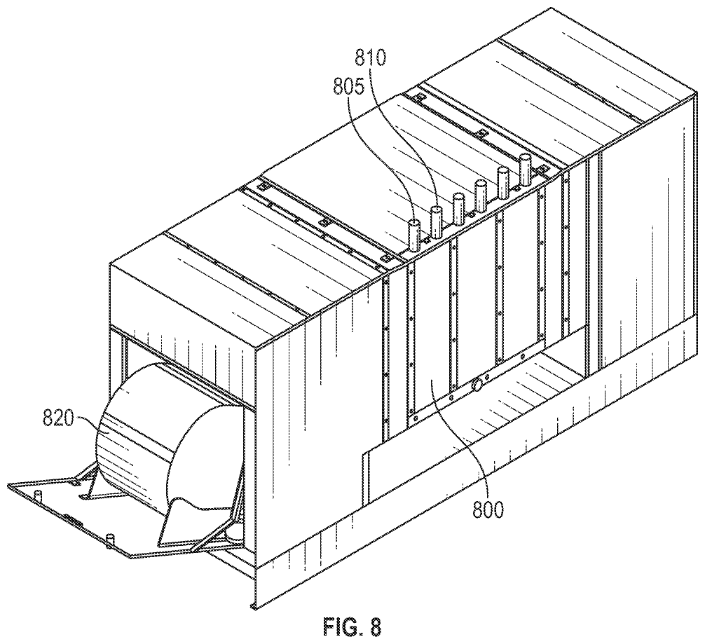

FIG. 7 shows a top section of the rack, illustrating the plate 700 which can be held on the rack in order to hold electrical connection parts.

In operation, the rack is closed at the top, and fitted with cooling equipment 800 shown in FIG. 8. The cooling part includes coils that are provided with cooling fluid via the pipes 805 810 and others. The cooled coils cause cooling in the cabinet using the blower 820 which recirculates air in the cabinet over the cooled coils.

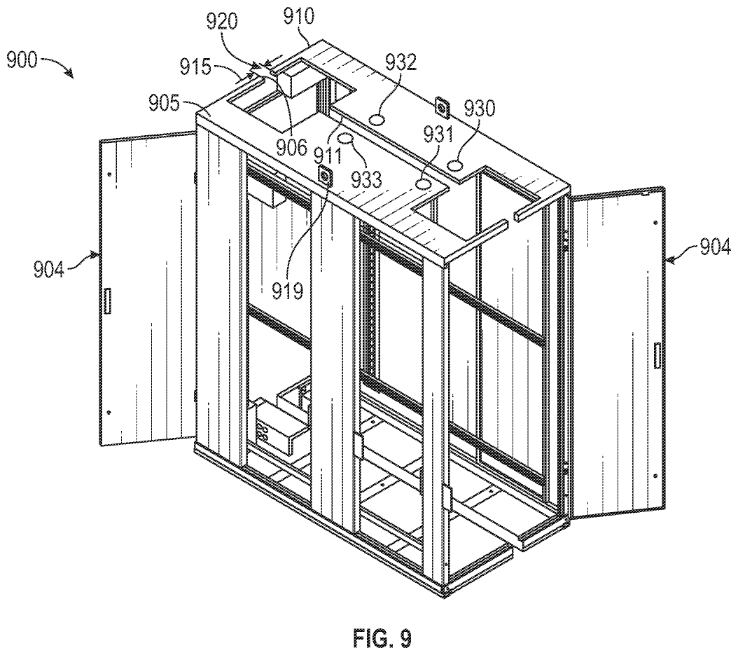

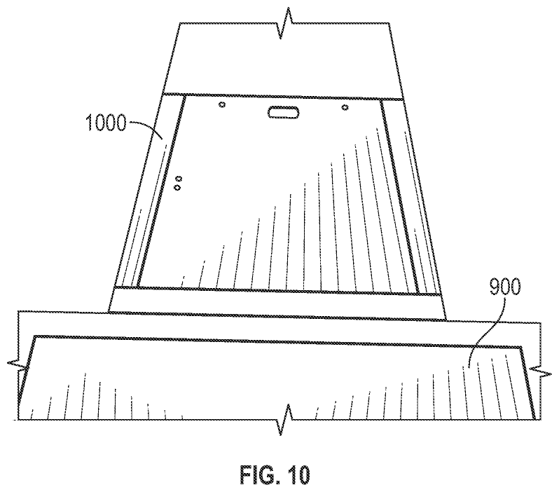

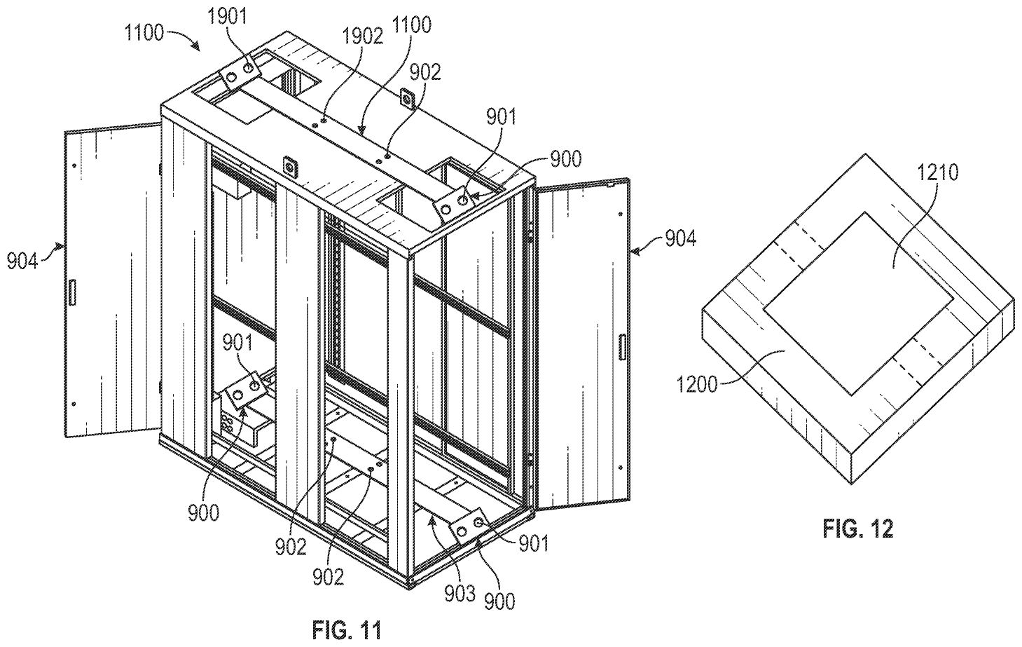

FIG. 9 shows the entire bottom portion 900 of the rack and shows how the bottom structure can allow width adjustability in this rack. The bottom structure 900 in FIG. 9 can be stretched in width as needed for an application. FIG. 10 shows how a top rack portion 1000 is placed on top of the bottom portion 900. The top rack portion 1000 is always the same size, and forms an interface with the cooling parts and electrical interface for the rack. The top rack portion 1000 can be attached to the top rack holding portions such as 919.

The bottom rack portion 900 in FIG. 9 includes a left side portion 905 and a right side portion 910, which are separated by a separation area 915, which can be a location where the left side portion 905 and right side portion 910 come together. The rack can be stretched in width by increasing the size of the gap 915. In one embodiment, when the rack is at its minimum size, the left side portion 905 has surfaces 906 that abut directly against corresponding surfaces 911 of the right side portion 910 when the rack is at its minimum size. In other embodiments, when the rack is expanded, such as shown in FIG. 9, there is a distance 920 between the surfaces 906 and 911.

Once adjusted in this way, FIG. 11 shows a guide plate 1100 being attached to the adjustment holes 930, 931, 932, 933. The guide plate 1100 can be attached by screwing into the holes, or by using a quick connect connector, to hold the rack into its expanded position.

In an embodiment the glide plate 1100 can be 12″ in width and allows the rack to change size as an adjustment to the size of the rack. The total adjustment is able to increase the width 920, e.g., up to 8″ in FIG. 9 by tightening guide plate into position.

The guide plate 1100 has lock downs 901 and 1901 at front and rear respectively When the rack has been adjusted to appropriate size, pins or bolts can be inserted, allowing the rack to be locked in place and preventing any further movement of the rack parts. Additional adjustment and tightening can also be used via lock down bolts 902, 1902 that are held in the holes 930, 931, 932, 933 respectively.

Based on the final rack width, a door 904 of appropriate width is installed as in FIG. 9. A different width door is used for different widths of racks,

In operation, when the rack is increased in width, the size of the hole 950 at the top of the rack is correspondingly increased because the distance between the two sides of the holes is increased. A blanking plate 1200 is placed on top of the rack, which has a hole 1210 that is the size of the original hole in the rack, before the rack was expanded in size and hence which is the proper size for airflow. In this way, even though the rack is expanded in width, the blanking plate 1200 can be placed on top of the rank in in front and in back to maintain the size of the holes.

In operation, the vertical support 140 can be moved backward and forward depending on the desired length of the server. This can be used to accommodate different length servers, with smaller depth servers leaving more space behind the rack for airflow.

Although only a few embodiments have been disclosed in detail above, other embodiments are possible and the inventors intend these to be encompassed within this specification.

The previous description of the disclosed exemplary embodiments is provided to enable any person skilled in the art to make or use the present invention. Various modifications to these exemplary embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. An adjustable width equipment rack, comprising:
an equipment rack, having a bottom surface, a top surface, sidewalls extending between the top and bottom surfaces, and server racks extending along the sidewalls supporting computer components, between a front surface and a rear surface;
the equipment rack having a left side and a right side which are movable relative to one another, the left side and right side being moved further from one another to increase a width of the rack, and being moved closer to one another to decrease a width of the rack,
an area of the rack where the left side meets the right side having adjustment guide plates, the guide plates being tightened to hold the rack in an adjusted position which includes in a first position a first width, and includes in a second position a second width narrower than the first width, where the rack is held by the guide plates in an adjusted width; and
an interface for a door, attached to the rack, which covers openable portions of the rack.

2. The rack as in claim q, wherein the door is a different door for the first width rack and is a second narrower door for the second width rack.

3. The rack as in claim 1, wherein the guide plate is attached to the rack by pins which hold the guide plate covering a space between the left side and the right side.

4. The rack as in claim 3, wherein the guide plate is attached to a top portion of the rack, to hold and cover the distance between the left side and the right side on the top portion of the rack.

5. The rack as in claim 4, further comprising another guide plate on the bottom portion of the rack to hold the distance between the left side and the right side on the bottom portion of the rack.

6. The rack as in claim 1, further comprising an opening in the top of the rack, through which airflow is received into the rack, and where the opening is configured such that the opening gets larger when the rack is increased in width and gets smaller when the rack is decreased in width.

7. The rack as in claim 6, further comprising a blanking plate, having an opening which is the size of the rack opening when the rack is at its minimum width, the blanking plate covering the opening in the top of the rack when the rack is adjusted to be increased in size.
